(19) United States
(12) Patent Application Publication
(10) Pub. No.: US 2002/0060339 A1
(43) Pub. Date: May 23, 2002

(54) Semiconductor device having field effect transistor with buried gate electrode surely overlapped with source region and process for fabrication thereof

(76) Inventor: Michiaki Maruoka, Shiga (JP)

Correspondence Address: ROSENMAN & COLIN LLP, 575 MADISON AVENUE, NEW YORK, NY, 10022-2585, US

(21) Appl. No.: 09/988,964

(22) Filed: Nov. 19, 2001

(30) Foreign Application Priority Data
Nov. 20, 2000 (JP) 2000-353072

(51) Int. Cl. H01L 29/76; H01L 29/94; H01L 21/8238; H01L 21/336

(52) U.S. Cl. 257/330; 257/328; 257/329; 438/212; 438/268; 438/259

(57) ABSTRACT

A buried gate type power field effect transistor has a drain layer forming a lower part of a silicon substrate, a base layer forming another part of the silicon substrate on the lower part, a source region forming a surface portion of the silicon substrate on the another part, a gate insulating layer covering an inner surface of a groove penetrating from the surface of the silicon substrate through the source region and the base region into the drain region and a polysilicon gate electrode filling the secondary groove defined by the gate insulating layer, wherein the gate electrode is formed with a recess exposed to the upper surface thereof and covered with an insulating layer defining a secondary recess filled with a piece of polysilicon so as to reduce the effective width of the gate electrode, thereby creating the upper surface substantially coplanar with the surface of the source region in spite of an etch back carried on a polysilicon layer for forming the gate electrode.

### FIELD OF THE INVENTION

This invention relates to a semiconductor device and, more particularly, to a semiconductor device fabricated on a semiconductor substrate with a buried gate electrode and a process for fabrication thereof.

### DESCRIPTION OF THE RELATED ART

A typical example of the semiconductor device is a power field effect transistor. The prior art power field effect transistor has plural unit cells each exhibiting the transistor function. The plural unit cells are connected in parallel, and, accordingly, the power field effect transistor is capable of flowing a large amount of electric current. The gate electrodes of the plural unit cells respectively create conductive channels inside the semiconductor substrate, and this structure is hereinbelow referred to as “buried gate structure”. The prior art buried gate type field effect transistor is more preferable than the gate planer type field effect transistor from the viewpoint of the integration density of the unit cells. When the prior art buried gate type field effect transistor is designed to be same in integration density as the gate planer type field effect transistor, each unit cell has the channel wider than that of the gate planer type field effect transistor. This results in a low on-resistance.

FIG. 1 illustrates a typical example of the buried gate type power field effect transistor 100. The prior art buried gate type power field effect transistor 100 is designed to have the source-drain withstanding voltage of 20-60 volts.

The prior art buried gate type power field effect transistor 100 is fabricated on a silicon substrate 1. The silicon substrate 1 has a heavily doped n-type silicon foundational layer 2 and an epitaxial silicon layer 4. A U-letter shaped groove 3 is formed in the epitaxial silicon layer 4, and is open to the major surface of the epitaxial silicon layer 4. The inner surface of the epitaxial silicon layer 4 exposed to the U-letter shaped groove 3 is covered with gate oxide layers 5, and, accordingly, the gate oxide layers 5 define a secondary groove. The secondary groove is buried with polysilicon, and the polysilicon is formed into gate electrodes 6 of the unit cells.

The epitaxially silicon layer 4 is divided into two silicon layers 7 and 8. The lower silicon layer 7 is lightly doped with n-type dopant impurity, and bottom portions of the U-letter shaped groove 3 is defined in the lightly doped n-type epitaxial silicon layer 7. The n-type epitaxial silicon layer 7 serves as drain regions of the unit cells, and is hereinbelow referred to as “n-type drain layer 7”. On the other hand, the upper silicon layer 8 is doped with p-type dopant impurity, and is hereinbelow referred to as “p-type base layer 8”. The U-letter shaped groove 3 divides the p-type base layer 8 into plural p-type base regions 8, and the plural p-type base regions 8 are electrically isolated by the upper portions of the U-letter shaped groove 3 and the p-n junctions between the n-type drain layer 7 and the p-type base layer 8.

The p-type base layer 8 is partially heavily doped with the p-type dopant impurity, and the heavily doped p-type base layer 8 is hereinbelow referred to as “heavily doped p-type back gate regions 9. Surface portions of the heavily doped p-type back gate regions 9 and surface portions of the p-type base layer 8 are heavily doped with the n-type dopant impurity, and the heavily doped n-type dopant impurity forms heavily doped n-type source regions 10. The heavily doped p-type back gate regions 9 are partially overlapped with the heavily doped n-type source regions 10.

The gate electrodes 6 are covered with an inter-level insulating layer 11, and the inter-level insulating layer 11 is partially removed so that the heavily doped n-type source regions 10 and the heavily doped p-type back gate regions 9 are partially exposed to the window formed in the inter-level insulating layer 11. A source electrode 12 is formed on the inter-level insulating layer 11. The source electrode 12 penetrates through the window, and is held in ohmic contact with the exposed surfaces of the heavily doped n-type source regions 10 and the exposed surfaces of the heavily doped p-type back gate regions 9.

The source electrode 12 serves as a source pad to be connected to an external power source. The U-letter shaped groove 3 is designed to have the width of the order of 0.5 micron on the mask pattern, and makes the prior art buried gate type field effect transistor achieve the source-and-drain withstanding voltage of 20-60 volts.

The prior art buried gate type power field effect transistor is fabricated as follows. The process starts with preparation of the heavily doped n-type silicon foundational layer 2. The silicon is epitaxially grown on the heavily doped n-type silicon foundational layer 2, and forms the epitaxial silicon layer 4. A photo-resist etching mask (not shown) is patterned on the epitaxial silicon layer 4, and the epitaxialy silicon layer 4 is selectively etched so that the U-letter shaped groove 3 is formed therein. The U-letter shaped groove 3 is designed to achieve the target source-and-drain withstanding voltage. In this instance, the U-letter shaped groove 3 measures 1.2 to 2.2 microns deep, and the width is of the order of 0.5 micron on the mask pattern. The photo resist etching mask is stripped off.

Subsequently, the epitaxial silicon layer 4 is thermally oxidized so that a silicon oxide layer is grown on the exposed surface of the epitaxial layer 4. The silicon oxide layer in the U-letter shaped groove 3 is to serve as the gate oxide layers 5, and defines the secondary groove. Polysilicon is deposited over the entire surface of the silicon oxide layer 5 by using a low pressure chemical vapor deposition technique. The secondary groove is filled with the polysilicon. The polysilicon swells into a polysilicon layer 13 as shown in FIG. 2A.

The polysilicon layer 13 is etched away without any mask until the silicon oxide layer 5 is exposed. The silicon oxide layer 5 serves as an etching stopper. The polysilicon is left on the secondary groove, and the gate electrodes 6 are obtained as shown in FIG. 2B. The gate electrodes 6 have the top surfaces, and the difference between the top surfaces and the upper surface of the epitaxial silicon layer 4 is equal to or less than 0.1 micron. The resultant structure is shown in FIG. 2B.

The silicon oxide layer 5 is removed from the upper surface of the epitaxial silicon layer 4. The exposed surface of the epitaxial silicon layer and the top surfaces of the gate electrodes 6 are thermally oxidized, again, so that a thin silicon oxide layer 14 is grown. Using the gate electrodes 6 as an ion-implantation mask, boron is ion implanted into the epitaxial silicon layer 4 through the thin silicon oxide layer 14, and is, thereafter, driven into the epitaxial silicon layer 4 through a thermal diffusion. The boron forms the p-type base layer 8, and the remaining portion of the epitaxial silicon layer 4 serves as the lightly doped n-type drain layer 7. The depth over which the boron is to be diffused is depending upon the withstanding voltage. In this instance, the p-type base layer 8 is fallen within the range from 1.0 micron deep to 1.8 microns deep.

A photo resist ion-implantation mask (not shown) is formed on the thin silicon oxide layer 14, and boron or boron fluoride is ion implanted into the p-type base layer 8. The photo resist ion-implantation mask is stripped off, and the ion-implanted boron or boron fluoride is thermally diffused. Then, the heavily doped p-type back gate regions 9 are formed in the p-type base layer 8.

A photo resist ion-implantation mask (not shown) is formed on the thin silicon oxide layer 14, and the p-type base layer 8 and the heavily doped p-type back gate regions 9 are partially covered with the photo resist ion-implantation mask. Using the photo resist ion-implantation mask and the gate electrodes 6 as a mask, arsenic or phosphorous is ion implanted into the exposed surface portions. The photo resist ion-implantation mask is stripped off, and the ion-implanted arsenic or phosphorous is thermally diffused. The arsenic or phosphorous forms the heavily doped n-type source regions 10. The heavily doped n-type source regions 10 are of the order of 0.4 micron deep.

Subsequently, insulating material is deposited over the entire surface of the resultant structure by using a chemical vapor deposition technique so as to form the inter-level insulating layer 11. A photo resist etching mask (not shown) is patterned on the inter-level insulating layer 11, and the inter-level insulating layer 11 and the thin silicon oxide layer 14 are selectively etched so that the window is formed in the inter-level insulating layer 11. The heavily doped n-type source regions 10 and the heavily doped p-type back gate regions 9 are partially exposed to the window. The photo resist etching mask is stripped off

Aluminum is deposited over the entire surface of the inter-level insulating layer 11 by using a sputtering technique so that an aluminum layer is formed A photo resist etching mask (not shown) is patterned on the aluminum layer, and the aluminum layer is selectively removed by using a dry etching technique. Then, the source electrode 12 is formed from the aluminum layer, and is held in ohmic contact with the heavily doped n-type source regions 10 and the heavily doped p-type back gate regions 9. A part of the source electrode 12 serves as the source pad to be electrically connected to the external power source. Though not shown in the drawings, the gate electrodes 6 are electrically connected through a polysilicon layer concurrently formed together with the gate electrodes 6, and the polysilicon layer is overlaid by an aluminum layer also concurrently formed together with the source electrode 12. The polysilicon layer and the aluminum layer are terminated at a gate pad (not shown), and the unit cells are biased through the gate pad.

FIG. 3 shows another prior art buried gate type power field effect transistor 200. The prior art buried gate type power field effect transistor 200 is targeted at the source-and-drain withstanding voltage between 150 volts and 250 volts. The following description is made on the assumption that the prior art buried gate type power field effect transistor 200 is perfectly completed.

Reference numeral 21 designates a silicon substrate. The silicon substrate 21 is implemented by the combination of a heavily doped n-type silicon foundational layer 22 and an epitaxial silicon layer 24. A U-letter shaped groove 23 is formed in the epitaxial silicon layer 24, and is open to the upper surface of the epitaxial silicon layer 24. The inner surface of the epitaxial silicon layer 24 is covered with gate oxide layers 25, and the gate oxide layers 25 define secondary groove in the U-letter shaped groove 23. The secondary groove is filled with polysilicon, and the polysilicon forms gate electrodes 26 of the unit cells in the secondary groove.

The epitaxial silicon layer 24 is divided into a lightly doped n-type drain layer 27 and a p-type base layer 28. The U-letter shaped groove 23 penetrates through the p-type base layer 28 into the lightly doped n-type drain layer 27. The p-type base layer 28 is separated into plural p-type base regions 28 by the U-letter shaped groove 23. Heavily doped p-type back gate regions 29 are formed in surface portions of the p-type base layer 28, and heavily doped n-type source regions 30 are further formed in other surface portions of the p-type base layer 28. The heavily doped p-type back gate regions 29 are partially overlapped with the heavily doped n-type source regions 30, respectively. The epitaxial silicon layer 24 and the polysilicon gate electrodes 26 are covered with an inter-level insulating layer 31, and a contact window is formed in the inter-level insulating layer 31. A source electrode 32 is formed on the inter-level insulating layer 31. The source electrode 32 penetrates through the contact window, and is held in contact with the heavily doped n-type source regions 30 and the heavily doped p-type back gate regions 30. The prior art buried gate type power field effect transistor is targeted at the withstanding voltage between 150 volts to 250 volts, and, accordingly, the U-letter shaped grooves 23 are designed to be 1.5 microns to 3.0 microns wide on the mask pattern. In this instance, the U-letter shaped groove 23 is 2.0 microns wide.

The prior art buried gate type power field effect transistor shown in FIG. 3 is fabricated as follows. The process starts with preparation of the heavily doped n-type silicon foundational layer 22 as similar to the prior art process shown in FIGS. 2A to 2C. Lightly doped n-type silicon is epitaxially grown on the heavily doped n-type silicon foundational layer 22, and the epitaxial silicon layer 24 is formed on the heavily doped n-type silicon foundational layer 22.

A photo resist etching mask (not shown) is formed on the epitaxial silicon layer 24. Using the photo resist etching mask, the epitaxial silicon layer 24 is selectively etched so that the U-letter shaped groove 23 is formed in the epitaxial silicon layer 24. The target withstanding voltage is taken into account. The U-letter shaped groove 23 is 1.5-2.5 microns deep, and the width is 1.5 to 3.0 microns on the mask pattern. The resultant structure is placed on a high temperature oxidation atmosphere, and a silicon oxide layer 25 is thermally grown on the exposed surfaces of the epitaxial silicon layer 24. The silicon oxide layer 25 on the inner surfaces defining the U-letter shaped groove 23 serves as the gate oxide layers of the unit cells. The gate oxide layers 25 define the secondary groove. The photo resist etching mask is stripped off.

Subsequently, polysilicon is deposited over the entire surface of the resultant structure by using the low pressure chemical vapor deposition technique. The polysilicon fills the secondary groove, and swells into a polysilicon layer 33 of 2-5 microns thick. The polysilicon layer 33 is created with a flat upper surface as shown in FIG. 4A.

The polysilicon layer 33 is subjected to a dry etching without any mask. The silicon oxide layer 25 serves as an etching stopper. The polysilicon layer 33 is removed from the upper surface of the epitaxial silicon layer 24, and the polysilicon is left in the secondary groove. However, the piece of polysilicon or the gate electrodes 26A of the unit cells have the upper surfaces lower than the upper surface of the epitaxial layer 24 by 0.4 micron or more as shown in FIG. 4B.

The silicon oxide layer 25 is etched away from the upper surface of the epitaxial silicon layer 24. The surface portion of the epitaxial layer 24 and the surface portions of the gate electrodes 26A are thermally oxidized so that a thin silicon oxide layer 34 is grown on the upper surface of the epitaxial layer 24 and the upper surfaces of the gate electrodes 26A.

Using the gate electrodes 26A as an ion implantation mask, boron is ion implanted into the epitaxial silicon layer 24 through the silicon oxide layer 34, and the ion-implanted boron is thermally diffused so as to form the p-type base layer 28. The remaining portion of the epitaxial silicon layer 24 serves as the lightly doped n-type drain layer 27. The p-n junction between the lightly doped n-type drain layer 27 and the p-type base layer 28 is depending upon the withstanding voltage. In this instance, the p-n junction is formed 1.3-2.1 microns deep.

A photo resist ion-implantation mask (not shown) is patterned on the thin silicon oxide layer 34 for the heavily doped p-type back gate regions 29. Using the photo resist ion-implantation mask, boron or boron fluoride is ion implanted into the surface portions of the p-type base layer 28. The photo resist ion-implantation mask is stripped off, and the boron or boron fluoride is thermally diffused. Then, the boron or boron fluoride forms the heavily doped p-type back gate regions 29.

Another photo resist ion-implantation mask (not shown) is patterned on the thin silicon oxide layer 34 for the heavily doped n-type source regions 30. Using the photo resist ion-implantation mask and the gate electrodes 26A as a mask, the arsenic or phosphorous is ion implanted into the surface portions of the epitaxial layer 24. The photo resist ion-implantation mask is stripped off, and the arsenic or phosphorous is thermally diffused so as to form the heavily doped n-type source regions 30. The heavily doped n-type source regions 30 have the depth of the order of 0.4 micron.

The thin silicon oxide layer 34 is etched away, and the inter-level insulating layer 31 is formed on the epitaxial silicon layer 24. The contact window is formed in the inter-level insulating layer 31, and the source electrode 32 and the gate pad are formed as similar to the prior art buried gate type power field effect transistor shown in FIG. 1.

Malfunction is less liable to take place in the prior art buried gate type power field effect transistor 100. However, a problem is encountered in the buried gate type power field effect transistor 200 in that the conductive channels are liable to be disconnected from the heavily doped n-type source regions 30. This is because of the fact that the upper surfaces of the polysilicon gate electrodes 26A are deepened when the U-letter shaped groove 23 is widely opened for the high withstanding voltage. In the prior art buried gate type power field effect transistor 200, the upper surfaces of the polysilicon gate electrodes 26A are as deep as 0.4 micron in the U-letter shaped groove 23, and the p-n junction between the heavily doped n-type source regions 30 and the p-type base layer 28 is of the order of 0.4 micron deep. If the polysilicon gate electrodes 26A are slightly over-etched, or if the arsenic or phosphorous is shallowly driven in the thermal diffusion, the conductive channel can not reach the heavily doped n-type source regions 30, and the malfunction takes place in the unit cells with the channel spaced from the heavily doped n-type source regions 30.

### SUMMARY OF THE INVENTION

It is therefore an important object of the present invention to provide a buried gate type semiconductor device, which surely creates a conductive channel between a source region and a drain region regardless of the width of a groove.

It is also an important object of the present invention to provide a process for fabricating the buried gate type semiconductor device.

To accomplish the object, the present invention proposes to reduce the effective width of a polysilicon layer serving as gate electrodes of unit cells.

In accordance with one aspect of the present invention, there is provided a semiconductor device comprising a semiconductor substrate formed with at least one groove open to a major surface thereof, a first etching stopper layer formed of a first material extending on an inner surface in such a manner as to define a secondary groove, a first filler formed of a second material larger in etching speed to a first etchant than the first material in the secondary groove and having a recess open to a surface thereof substantially coplanar with the major surface, a second etching stopper layer formed of a third material extending on an inner surface in such a manner as to define a secondary recess, and a second filler formed of a fourth material larger in etching speed to a second etchant than the third material in the secondary recess so as to reduce a width of the first filler together with the second etching stopper.

In accordance with another aspect of the present invention, there is provided a semiconductor device comprising plural unit cells formed in a semiconductor substrate and connected in parallel to one another, and each of the plural unit cells includes a drain region of a first conductivity type formed in the semiconductor substrate, a base region contiguous to the drain region for creating a conductive channel connected to the drain region and having a second conductivity type opposite to the first conductivity type, a source region of the first conductivity type contiguous to the base region and having a surface substantially coplanar with a major surface of the semiconductor substrate, a gate insulating layer extending on an surface of a groove penetrating from the surface of the source region through the base region into the drain region and defining a secondary groove and a gate electrode filling the secondary groove so as to be opposed to the base region through the gate insulating layer and having an insulating layer covering a recess formed in a surface portion thereof in such a manner as to define a secondary recess and a piece of material filling the secondary recess so as to reduce the width of the gate electrode.

In accordance with yet another aspect of the present invention, there is provided a process for fabricating a semiconductor device, comprising the steps of a) preparing a semiconductor substrate having a major surface, b) forming a groove penetrating from the major surface into the semiconductor substrate, c) covering an inner surface of the semiconductor substrate defining the groove and the major surface with a first etching stopper layer of a first material in such a manner that the first etching stopper layer defines a secondary groove, d) depositing a second material larger in etching speed to a first etchant than the first material so that the second material fills the secondary groove in such a manner that a recess takes place in a surface portion of a piece of the second material and forms a layer on the major surface of the semiconductor substrate, e) covering an inner surface of the piece of the second material defining the recess and an exposed surface of the layer of the second material with a second etching stopper layer formed of a third material in such a manner that the second etching stopper layer defines a secondary recess, f) depositing a fourth material larger in etching speed to a second etchant than the third material so that the fourth material fills the secondary recess and forms a layer over the major surface, g) etching the layer of the fourth material by using the second etchant until the second etching stopper layer over the major surface is exposed so that a piece of fourth material is left in the secondary recess, h) removing the second etching stopper layer from the layer of the second material over the major surface so that the layer of the second material is exposed, i) etching the layer of the second material by using the first etchant until the first etching stopper layer on the major surface is exposed so that a piece of the second material is left in the secondary groove together with a part of the second etching stopper layer and a piece of fourth material, and j) completing a semiconductor element having the piece of the piece of the second material and a part of the first etching stopper as component parts thereof.

### BRIEF DESCRIPTION OF THE DRAWINGS

The features and advantages of the semiconductor device and the process will be more clearly understood from the following description taken in conjunction with the accompanying drawings in which:

FIG. 1 is a cross sectional view showing the structure of the prior art buried gate type power field effect transistor;

FIGS. 2A to 2C are cross sectional views showing the prior art process for fabricating the buried gate type power field effect transistor;

FIG. 3 is a cross sectional view showing the structure of another prior art buried gate type power field effect transistor;

FIGS. 4A to 4C are cross sectional views showing the prior art process for fabricating the prior art buried gate type power field effect transistor;

FIG. 5 is a cross sectional view showing the structure of a buried gate type power field effect transistor according to the present invention;

FIG. 6 is a schematic view showing the layout of unit cells forming parts of the power field effect transistors; and

FIGS. 7A to 7E are cross sectional views showing a process for fabricating the power field effect transistor according to the present invention.

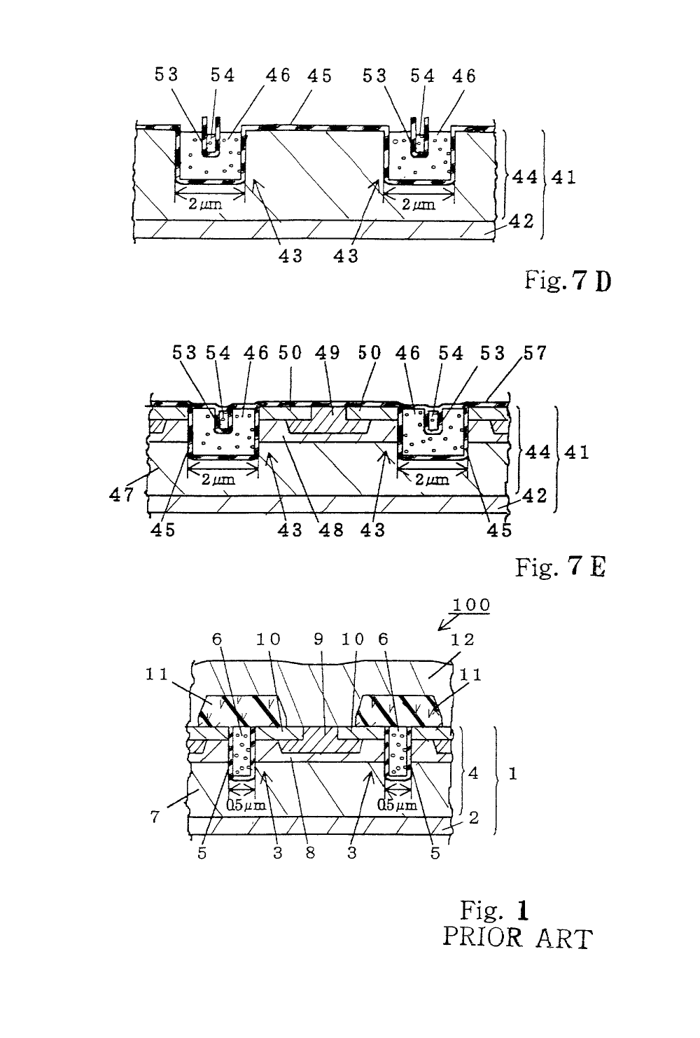

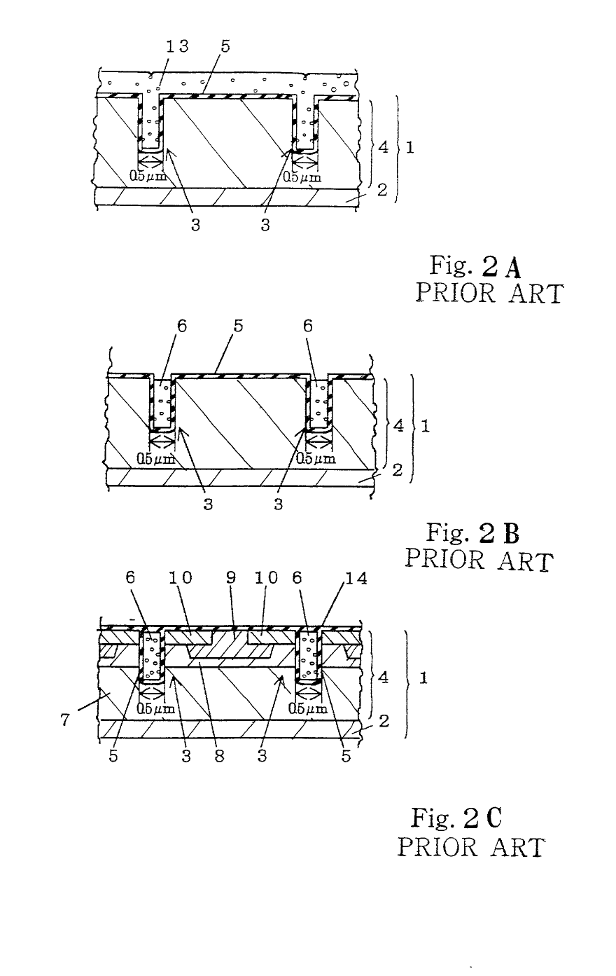

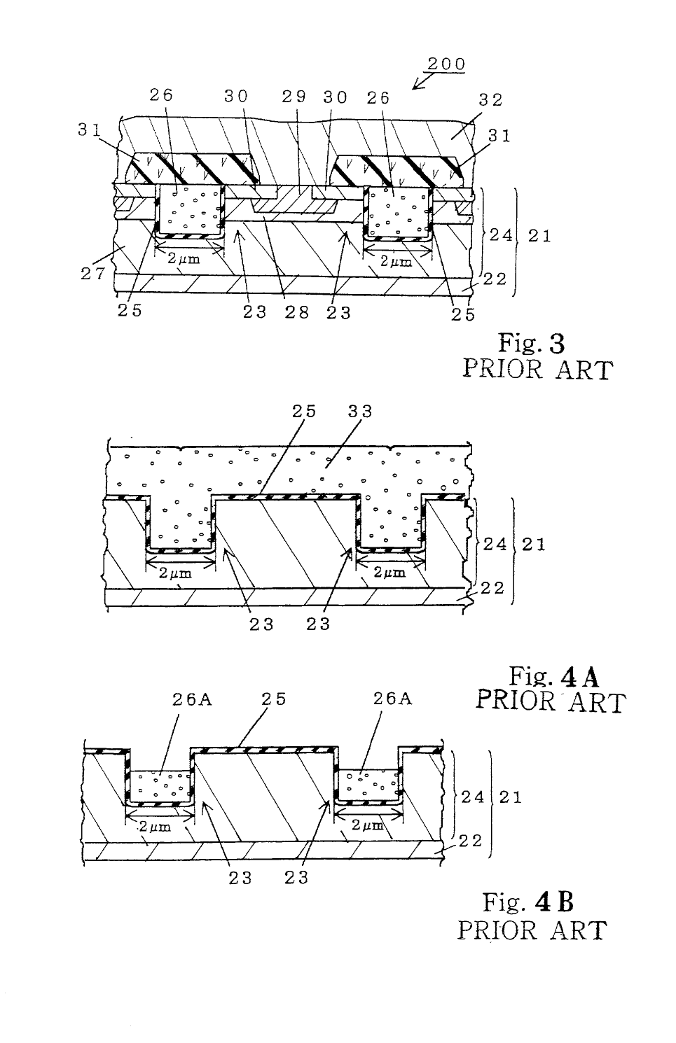

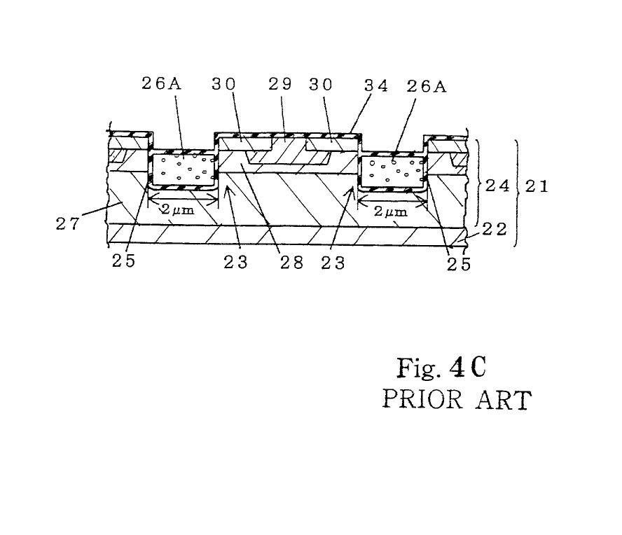

### DESCRIPTION OF THE PREFERRED EMBODIMENT

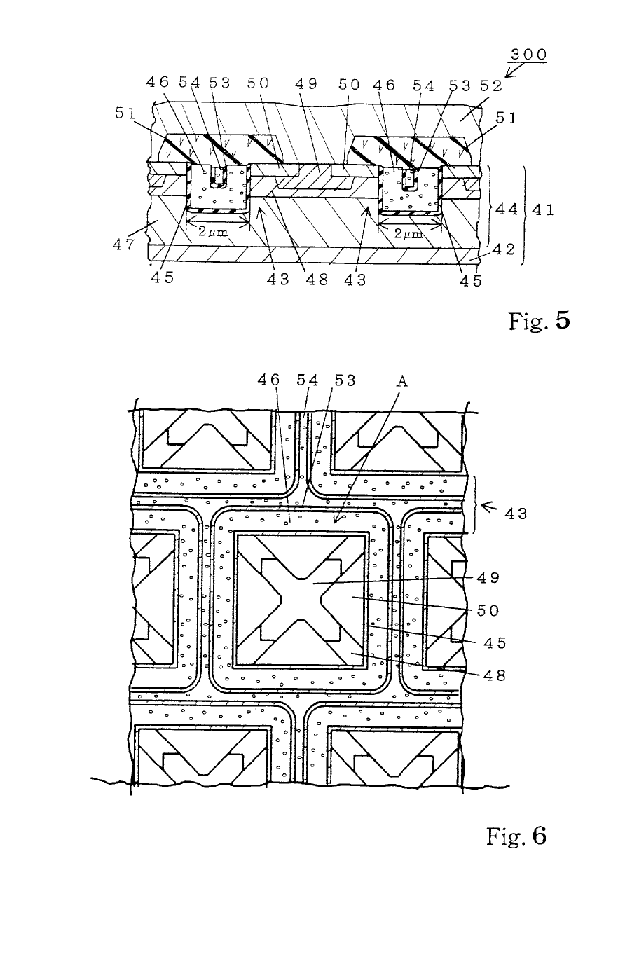

Referring to FIG. 5 of the drawings, a buried gate type power field effect transistor embodying the present invention is designated by reference numeral 300. The buried gate type power field effect transistor 300 is fabricated on a silicon substrate 41. A heavily doped n-type silicon foundational layer 42 and an epitaxial silicon layer 44 form in combination the silicon substrate 41. A U-letter shaped groove 43 is formed in the epitaxial silicon layer 44, and is open to the upper surface of the epitaxial silicon layer 44.

The epitaxial silicon layer 44 includes a lightly doped n-type drain layer 47 and a p-type base layer 48. The lightly doped n-type drain layer 47 is laminated on the heavily doped n-type silicon foundational layer 42, and is overlaid by the p-type base layer 48. The U-letter shaped groove 43 penetrates into the lightly doped n-type drain layer, and separates the p-type base layer 48 into plural p-type base regions.

The inner surface of the epitaxial silicon layer 44 defining the U-letter shaped groove 43 is covered with gate insulating layers 45 of unit cells, and the gate insulating layers 45 define a secondary groove. The secondary groove is respectively filled with polysilicon, which provides gate electrodes 46 for the unit cells. A narrow groove is formed in a surface portion of the polysilicon layer, and the inner surface of the polysilicon layer is covered with a silicon oxide layer 53. The silicon oxide layer 53 defines a recess, and the recess is spaced from the gate oxide layers 45. The recess is filled with a polysilicon layer 54. Thus, the polysilicon layer 54 is nested in the polysilicon layer serving as the gate electrodes 46, and reduces the width of the gate electrodes 46. The target source-and-drain withstanding voltage is 150 volts to 250 volts, and, accordingly, the U-letter shaped groove 43 ranges from 1.5 micron wide to 3.0 micron wide in a mask pattern. In this instance, the U-letter shaped groove 43 is designed to have the width of the order of 2.0 microns. However, the polysilicon layer 54 and the silicon oxide layer 53 reduce the width of the polysilicon layer or the gate electrodes 46 in the surface portion. The polysilicon layer or the gate electrodes 46 with the narrowed surface portion is effective against the depression of the upper surfaces of the gate electrodes 46. In fact, the upper surfaces of the gate electrodes 46 are substantially coplanar with the upper surface of the epitaxial silicon layer 47.

Heavily doped p-type back gate regions 49 are formed in surface portions of the p-type base regions, and are spaced from the gate oxide layers 45, respectively. Heavily doped n-type source regions 50 are formed in surface portions between the gate oxide layers 45 and the heavily doped p-type back gate regions 49, and are partially overlapped with the heavily doped p-type back gate regions 49. As described hereinbefore, the gate electrodes 46 have the upper surface substantially coplanar with the upper surface of the epitaxial silicon layer 44. Accordingly, the heavily doped n-type source regions 50 have the bottom surfaces deeper than the upper surfaces of the associated gate electrodes 46. This results in that the conductive channels of the unit cells are surely created in such a manner as to connect the heavily doped n-type source regions 50 and the lightly doped n-type drain layer 47. The heavily doped n-type source region 50 and the part of the p-type base region therebeneath form one of the unit cells together with the gate insulating layer 45, the polysilicon gate electrode 46 and the lightly doped n-type drain layer 47.

The gate electrodes 46 and the epitaxial silicon layer 44 are covered with an inter-level insulating layer 51, and a contact window is formed in the inter-level insulating layer 51. The heavily doped source regions 50 and the heavily doped p-type back gate regions 49 are exposed to the contact window. A source electrode 52 is formed on the inter-level insulating layer 51, and is held in contact with the heavily doped n-type source regions 50 and the heavily doped p-type back gate regions 49. Though not shown in FIG. 5, a gate pad is further formed on the inter-level insulating layer 51, and is electrically connected to the polysilicon gate electrodes 46. Thus, the unit cells are connected in parallel between the source electrode 52 and the lightly doped drain layer 47, and form in combination a power field effect transistor.

The unit cells are arranged as shown in FIG. 6. The source electrode 52 and the inter-level insulating layer 51 are deleted from FIG. 6 for better understanding the layout. The unit cells are arranged in rows and columns, and the unit cells in each row are offset from the corresponding unit cells in the adjacent rows by a half pitch. The gate insulating layers 45 are exposed to the upper surface of the epitaxial layer 44, and define generally rectangular active areas A in the upper surface. The heavily doped n-type source regions 50 are respectively exposed in the rectangular active areas A, and occupy triangle sub-areas. The heavily doped p-type back gate regions occupy central sub-areas in the generally rectangular active areas A, and radially project in the direction of diagonal lines. The p-type base regions 48 are exposed to the surface sub-areas between the heavily doped p-type back gate regions 49 and the corners of the generally rectangular active areas.

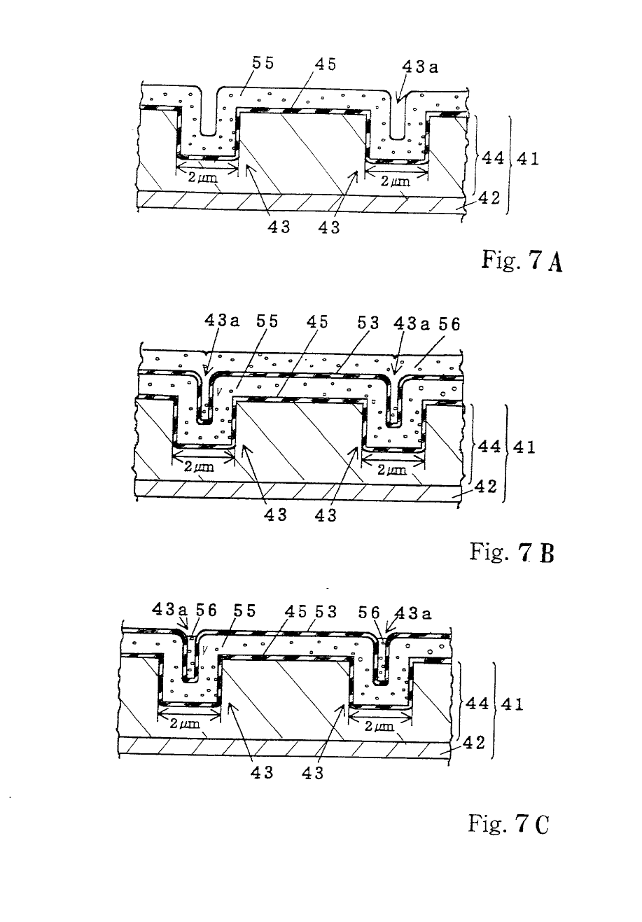

Description is made on a process for fabricating the buried gate type power field effect transistor with reference to FIGS. 7A to 7E. The process starts with preparation of the heavily doped n-type silicon foundational layer 42. Lightly doped n-type silicon is epitaxially grown on the heavily doped n-type silicon foundational layer 42, and forms the epitaxial silicon layer 44.

A photo resist etching mask (not shown) is patterned on the epitaxial silicon layer 44, and the area assigned to the U-letter shaped groove 43 is exposed to the hollow space of the photo resist etching mask. Using the photo resist etching mask, the epitaxial silicon layer 44 is selectively etched so that the U-letter shaped groove 43 is formed like a lattice. The U-letter shaped groove 43 is 1.5 microns to 2.5 microns deep and 1.5 microns to 3.0 microns wide depending upon the target source-and-drain withstanding voltage. The photo resist etching mask is stripped off.

The exposed surfaces of the epitaxial silicon layer 44 is thermally oxidized so that the epitaxial silicon layer 44 is covered with the silicon oxide layer, which partially serve as the gate insulating layers 45 in the U-letter shaped groove 43. The silicon oxide layer defines the secondary groove.

Subsequently, polysilicon is deposited to 1 microns thick over the entire surface of the silicon oxide layer 45 by using a low pressure chemical vapor deposition. The polysilicon in the secondary groove is not merged into any piece, and a recess 43a is defined by the polysilicon layer 55 a shown in FIG. 7A.

The resultant structure shown in FIG. 7A is laced in a high temperature oxidizing atmosphere, and the silicon oxide layer 53 is thermally grown on the exposed surface of the polysilicon layer 55. The silicon oxide layer 53 is as thin as the gate insulating layers 45. The silicon oxide layer 53 defines the recess. Polysilicon is deposited over the entire surface of the silicon oxide layer 53 by using the low pressure chemical vapor deposition technique. The polysilicon fills the recess, and swells into a polysilicon layer 56. The polysilicon layer 56 on the silicon oxide layer 53 ranges from 1 micron to 4 microns thick, and creates a substantially flat upper surface as shown in FIG. 7B.

The polysilicon layer 56 is subjected to an etch back by using a dry etching without any mask. The silicon oxide layer 53 serves as an etching stopper against the dry etchant, and a polysilicon layer 56 is left in the recess as shown in FIG. 7C.

Subsequently, the silicon oxide layer 53 is removed from the surface of the polysilicon layer 55 by using a wet etching technique. The polysilicon layer 55 is uniformly etched back by using the dry etching until the silicon oxide layer 45 is exposed. The silicon oxide layer 45 serves as an etching stopper, and the polysilicon layers 46 and 54 are left in the u-letter shaped groove 43 as shown in FIG. 7D.

The polysilicon layers 46 serve as the gate electrodes of the unit cells. Since the silicon oxide layer 53 and the polysilicon layer 54 reduces the effective width of the secondary groove, the dry etching does not seriously proceeds in the vertical direction, and the upper surfaces of the gate electrodes 46 are substantially coplanar with the upper surface of the epitaxial layer 44. Even though the polysilicon layer 46 is vertically etched, the difference between the upper surface of the epitaxial silicon layer 44 and the upper surface of the polysilicon layer 46 is equal to or less than 0.1 micron.

Subsequently, the silicon oxide layer 45 and the silicon oxide layer 53 over the polysilicon layer 46 are removed, and the exposed surface of the epitaxial silicon layer 44 and the upper surface of the polysilicon layer 46 are thermally oxidized so that the epitaxial silicon layer 44 and the polysilicon layer 46 are covered with the silicon oxide layer 57.

Using the gate electrodes 46 as a mask, boron is ion implanted into the epitaxial silicon layer 44, and the ion-implanted boron is driven into the epitaxial silicon layer 44. The diffused boron forms the p-type base layer 48. The remaining portion of the epitaxial silicon layer 44 serves as the lightly doped drain layer 47. The p-type base layer 48 is fallen within the range from 1.3 microns thick to 2.1 microns thick.

A photo resist ion implantation mask (not shown) is patterned on the p-type base layer 48, and the areas assigned to the heavily doped p-type back gate regions 49 are exposed to the hollow spaces of the photo resist ion implantation mask. Using the gate electrodes 46 and the photo resist ion implantation mask, boron or boron fluoride is ion implanted into the p-type base layer 48. The photo resist ion implantation mask is stripped off, and the ion-implanted boron or boron fluoride is thermally diffused so that the heavily doped p-type back gate regions 49 are formed in the p-type base regions 48.

Another photo resist ion implantation mask (not shown) is patterned on the epitaxial silicon layer 44, and the areas assigned to the heavily doped n-type source regions 50 are exposed to hollow spaces of the photo resist ion implantation mask. Using the gate electrodes 46 and the photo resist ion implantation mask, arsenic or phosphorous is ion implanted into the surface portions of the epitaxial silicon layer 44. The photo resist ion implantation mask is stripped off, and the ion-implanted arsenic or phosphorous is thermally diffused so that the heavily doped n-type source regions 50 are formed as shown in FIG. 7E. The heavily doped n-type source regions 50 are of the order of 0.4 micron deep.

Subsequently, insulating material is deposited over the entire surface of the resultant structure by using a chemical vapor deposition, and forms the inter-level insulating layer 51. A photo-resist etching mask (not shown) is patterned on the inter-level insulating layer 51, and the inter-level insulating layer 51 and the silicon oxide layer 57 are selectively etched so that the contact window is formed in the inter-level insulating layer 51. The heavily doped n-type source regions 50 and the heavily doped p-type back gate regions 49 are exposed to the contact window. The photo resist etching mask is stripped off.

Aluminum is deposited over the entire surface of the inter-level insulating layer 51. The aluminum fills the contact window, and swells into an aluminum layer. A photo resist etching mask (not shown) is patterned on the aluminum layer, and the aluminum layer is selectively etched so that the source electrode 52, the source pad connected to the source electrode 52 and the gate pad are formed on the inter-level insulating layer 51.

As will be appreciated from the foregoing description, the polysilicon layer 54 fills the recess formed in the surface portion of the polysilicon layer 55 so as to narrow the polysilicon layer 55 in the secondary groove. Even though the U-letter shaped groove 43 is widened for a large withstanding voltage, the polysilicon layer 56 in the recess formed by the silicon oxide layer 53 make the effective width of the polysilicon layer 56 narrower than the width of the secondary recess. As a result, when the polysilicon gate electrodes 46 are completed in the U-letter shaped groove, the upper surfaces of the polysilicon gate electrodes 46 are substantially coplanar with the upper surface of the epitaxial silicon layer 44. Since the heavily doped n-type source regions 50 penetrate into the epitaxial silicon layer 44, the bottom surfaces of the heavily doped n-type source regions 50 become deeper than the upper surfaces of the polysilicon gate electrodes 46. For this reason, when the polysilicon gate electrodes 46 are appropriately biased, the conductive channels surely reach the heavily doped n-type source regions, and the unit cells flow a large amount of current.

In the above-described embodiment, the silicon oxide layers 45 and 53 serve as a first etching stopper layer and a second etching stopper layer, respectively, and the polysilicon gate electrodes 46 and the polysilicon layer 54 are corresponding to a first filler and a second filler, respectively.

Although particular embodiments of the present invention have been shown and described, it will be apparent to those skilled in the art that various changes and modifications may be made without departing from the spirit and scope of the present invention.

For example, the unit cells may be arranged in a pattern different from that shown in FIG. 6. The unit cells are, by way of example, arranged in a stripe pattern. Otherwise, the unit cells may be arranged in rows and columns without any offset.

The active area A may be circle or polygonal. The heavily doped n-type source regions 50 may surround the other impurity region such as the heavily doped p-type back gate regions 49.

The power field effect transistor may be fabricated on the silicon foundational layer 42 without the epitaxial silicon layer 44. In this instance, the back surface portion of the silicon foundational layer 42 is heavily doped with n-type dopant impurity.

The n-type impurity regions/layers and the p-type impurity regions/layers may be exchanged so as to form a p-channel type power field effect transistor.

The present invention is applicable to another kind of semiconductor device such as, for example, IGBT. The buried polysilicon pieces may be formed in the groove for another purpose.

The first etching stopper layer may be different in material from the second etching stopper layer, and the first filler may be different in material from the second filler.

What is claimed is:

1. A semiconductor device comprising
a semiconductor substrate formed with at least one groove open to a major surface thereof,
a first etching stopper layer formed of a first material extending on an inner surface in such a manner as to define a secondary groove,
a first filler formed of a second material larger in etching speed to a first etchant than said first material in said secondary groove and having a recess open to a surface thereof substantially coplanar with said major surface,
a second etching stopper layer formed of a third material extending on an inner surface in such a manner as to define a secondary recess, and
a second filler formed of a fourth material larger in etching speed to a second etchant than said third material in said secondary recess so as to reduce a width of said first filler together with said second etching stopper.

2. The semiconductor device as set forth in claim 1, in which said first material and said third material are silicon oxide, and said second material and said fourth material are polysilicon.

3. The semiconductor device as set forth in claim 1, in which said first filler and said first etching stopper layer respectively serve as a gate electrode and a gate insulating layer both incorporated in a field effect transistor.

4. The semiconductor device as set forth in claim 3, in which said field effect transistor further includes a drain layer of a first conductivity type, a base layer formed on said drain layer and having a second conductivity type opposite to said first conductivity type and a source region of said first conductivity type formed in a surface portion of said base layer, and said at least one groove penetrates from a surface of said source region through said base region into said drain layer.

5. The semiconductor device as set forth in claim 4, in which said field effect transistor serves as a unit cell connected in parallel to other unit cells similar in structure to said unit cell and formed in said semiconductor substrate.

6. The semiconductor device as set forth in claim 1, in which said semiconductor substrate has an impurity region formed in a surface portion thereof and having a side surface held in contact with said first etching stopper layer, and said surface portion forms a p-n junction deeper than said surface of said first filler together with another portion of said semiconductor substrate thereunder.

7. The semiconductor device as set forth in claim 6, in which said semiconductor substrate further has yet another portion under said another portion and forming another p-n junction together with said another portion.

8. The semiconductor device as set forth in claim 7, in which said first filler, said first etching stopper layer, said surface portion, said another surface portion and said yet another surface portion serve as a gate electrode, a gate insulating layer, a source region, a channel region and a drain region, respectively.

9. The semiconductor device as set forth in claim 1, in which said at least one groove is equal to or greater than 1.5 microns wide.

10. A semiconductor device comprising plural unit cells formed in a semiconductor substrate and connected in parallel to one another, each of said plural unit cells including
a drain region of a first conductivity type formed in said semiconductor substrate,
a base region contiguous to said drain region for creating a conductive channel connected to said drain region and having a second conductivity type opposite to said first conductivity type,
a source region of said first conductivity type contiguous to said base region and having a surface substantially coplanar with a major surface of said semiconductor substrate,
a gate insulating layer extending on an surface of a groove penetrating from said surface of said source region through said base region into said drain region and defining a secondary groove, and
a gate electrode filling said secondary groove so as to be opposed to said base region through said gate insulating layer and having an insulating layer covering a recess formed in a surface portion thereof in such a manner as to define a secondary recess and a piece of material filling said secondary recess so as to reduce the width of said gate electrode.

11. The semiconductor device as set forth in claim 10, in which said gate insulating layer and said insulating layer are formed of silicon oxide, and said gate electrode and said piece of material are formed of polysilicon.

12. The semiconductor device as set forth in claim 10, in which said groove is equal to or greater than 1.5 microns wide.

13. The semiconductor device as set forth in claim 10, in which said plural unit cells are respectively assigned to active regions defined in said semiconductor substrate and exposed to said major surface in such a manner as to be laid on a pattern of rows and columns.

14. The semiconductor device as set forth in claim 13, in which said active regions in one of said rows are offset from the corresponding active regions in an adjacent row by a pitch equal to half of the active region.

15. A process for fabricating a semiconductor device, comprising the steps of:
a) preparing a semiconductor substrate having a major surface;
b) forming a groove penetrating from said major surface into said semiconductor substrate;
c) covering an inner surface of said semiconductor substrate defining said groove and said major surface with a first etching stopper layer of a first material in such a manner that said first etching stopper layer defines a secondary groove;
d) depositing a second material larger in etching speed to a first etchant than said first material so that said second material fills said secondary groove in such a manner that a recess takes place in a surface portion of a piece of said second material and forms a layer on said major surface of said semiconductor substrate;
e) covering an inner surface of said piece of said second material defining said recess and an exposed surface of said layer of said second material with a second etching stopper layer formed of a third material in such a manner that said second etching stopper layer defines a secondary recess;
f) depositing a fourth material larger in etching speed to a second etchant than said third material so that said fourth material fills said secondary recess and forms a layer over said major surface;
g) etching said layer of said fourth material by using said second etchant until said second etching stopper layer over said major surface is exposed so that a piece of fourth material is left in said secondary recess;
h) removing said second etching stopper layer from said layer of said second material over said major surface so that said layer of said second material is exposed;
i) etching said layer of said second material by using said first etchant until said first etching stopper layer on said major surface is exposed so that a piece of said second material is left in said secondary groove together with a part of said second etching stopper layer and a piece of fourth material; and
j) completing a semiconductor element having said piece of said piece of said second material and a part of said first etching stopper as component parts thereof.

16. The process as set forth in claim 15, in which said semiconductor element further has a drain layer of a first conductivity type forming a lower part of said semiconductor substrate, a channel layer having a second conductivity type opposite to said first conductivity type and forming another part of said semiconductor substrate on said lower part and a source region of said first conductivity type forming yet another part of said semiconductor substrate on said another part and exposed to said major surface, and said piece of said second material and said part of said first etching stopper layer serve as a gate electrode and said gate insulating layer, respectively.

17. The process as set forth in claim 15, in which said first material and said third material are silicon oxide.

18. The process as set forth in claim 17, in which said first etching stopper layer and said second etching stopper layer are formed by using a thermal oxidation technique respectively carried on said semiconductor substrate and said layer of second material in said steps c) and e).

19. The process as set forth in claim 15, in which said first material and said third material are silicon oxide, and said second material and said fourth material are polysilicon.

20. The process as set forth in claim 19, in which said first etching stopper layer and said second etching stopper layer are formed through a thermal oxidation technique in said steps c) and e), and said second material and said fourth material are deposited by using a chemical vapor deposition in said steps d) and f).
